(19) United States
(12) Patent Application Publication
(10) Pub. No.: US 2003/0211742 A1
(43) Pub. Date: Nov. 13, 2003

(54) CMP process for a damascene pattern

(76) Inventors: Akira Kubo, Tokyo (JP); Yasuaki Tuchiya, Tokyo (JP); Tomoko Wake, Tokyo (JP)

Correspondence Address: KATTEN MUCHIN ZAVIS ROSENMAN, 575 MADISON AVENUE, NEW YORK, NY, 10022-2585, US

(21) Appl. No.: 10/461,542

(22) Filed: Jun. 13, 2003

Related U.S. Application Data
(63) Continuation of application No. 10/015,973, filed on Nov. 1, 2001, now abandoned.

(30) Foreign Application Priority Data
Nov. 2, 2000 (JP) 2000-336277

(51) Int. Cl. H01L 21/302; H01L 21/461

(52) U.S. Cl. 438/691

(57) ABSTRACT

A CMP process includes the steps of polishing a Cu film of a damascene pattern having the Cu film and an underlying barrier film until the barrier film is exposed, cleaning the exposed surfaces of the Cu film and the barrier film by using aqueous ammonium for removing an organic Cu complex, washing the exposed surfaces of the Cu film and barrier film, and polishing the barrier film and the Cu film until an insulator film is exposed.

### BACKGROUND OF THE INVENTION

(a) Field of the Invention

The present invention relates to a CMP (Chemical-Mechanical Polishing) process for a damascene pattern and, more particularly, to a CMP process for use in forming a damascene interconnect pattern in a semiconductor device. The present invention also relates to a CMP system.

(b) Description of the Related Art

Some semiconductor integrated circuits (ICs) use a damascene technique wherein 2 an interconnect pattern called damascene pattern is embedded within a trench pattern formed on an interlevel dielectric film. The damascene interconnect pattern is generally subjected to a CMP process using a CMP system after filling the trench pattern and covering the interlevel dielectric film with a conductive film having a thickness larger than the depth of the trench pattern.

Referring to FIG. 1, a CMP system 100 includes a CMP plant 101 and a control unit 102 therefor, the CMP plant 101 including a first CMP unit 111, a second CMP unit 112 and a washing/drying unit 113 consecutively disposed from the inlet for the wafer to the outlet for the wafer. Each CMP unit 111 or 112 includes a pad member 120, a polishing-liquid supply member 121 and a rinsing-liquid supply member 122. A semiconductor wafer 200 is transferred to/from the CMP plant 101 by using a carriage system not shown.

Referring to FIG. 2A showing a sectional view of the semiconductor wafer 200, an interlevel dielectric film 202 made of silicon oxide is formed on a silicon substrate 201. The interlevel dielectric film 202 has therein a trench pattern 203, which is covered by a thin barrier film 204 within and outside the trench pattern 203. A Cu film 205 is formed on the thin barrier film 205 for filling the trench pattern 203 and covering the interlevel dielectric film 202.

Referring to FIG. 3, the first CMP unit 111 includes the pad member 120 made of urethane and pivotally mounted on a driving mechanism (not shown) by way of a surface plate 123 for rotation in a horizontal plane. The polishing-liquid supply member 121 and the rising-liquid supply member 122 are driven alternately with time to oppose the pad member 120 by using a driving unit not shown.

The polishing-liquid supply member 121 supplies polishing liquid or slurry onto the top surface of the pad member 120, whereas the rinsing-liquid supply member 122 supplies rinsing liquid or pure water onto the top of the pad member 120. The carriage system places the semiconductor wafer 200 onto the pad member 120 for rotation and for holding by a thrust member 110.

The second CMP unit 112 has a pad member 130, a polishing-liquid supply member 132 and a rinsing-liquid supply member 133, similarly to the first CMP unit 111. The first CMP unit 111 is dedicated to polishing the Cu film 205 shown in FIG. 2A, whereas the second CMP unit 112 is dedicated to polishing the tantalum barrier film 204 shown in FIG. 2A.

The polishing-liquid supply member 121 in the first CMP unit 111 supplies polishing liquid containing silica as an organic compound, whereas the polishing-liquid supply member 131 in thee second CMP unit 112 supplies polishing liquid containing alumina. The pad members 120 and 130 in the first and second CMP units 111 and 112 have different properties.

The process in the CMP system 100 is shown by FIG. 4. First, a semiconductor wafer 200 is held by the thrust member 110 and transferred to the first CMP unit 111 of the CMP system 100 in step S1. The semiconductor wafer 200 transferred to the CMP system 100 has the structure shown in FIG. 2A.

In step S2, the semiconductor wafer 200 is driven for rotation on the pad member 120, onto which the polishing-liquid supply member 121 supplies a polishing liquid.

The thrust member 110 thrusts the semiconductor wafer 200 against the pad member 120 at a higher pressure of 4 pounds per inch, (psi) during rotation of the pad member 120 to polish the Cu film 25, until the barrier film 204 is exposed from the Cu film 205 as shown in FIG. 2B.

In step S3, the trust pressure by the thrust member 110 is reduced from 4 to 1 psi, and the rising-liquid supply member supplies a rinsing liquid onto the pad member 120 for rinsing the semiconductor wafer 200.

After the polishing and rising steps are finished in the first CMP unit 111, the semiconductor wafer 200 is then transferred to the second CMP unit 112 in step S4 and subjected to a high pressure polishing for-the barrier film 204 at a thrust pressure of 4 psi. The polishing is conducted until the interlevel dielectric film 202 is exposed as shown in FIG. 2C.

The semiconductor wafer 200 is then subjected to a rinsing step using rinsing liquid after the thrust pressure is lowered to 1 psi in step S6, whereby the surface of the semiconductors wafer 200 is washed. After the polishing and rinsing steps are finished in the second CMP unit 112, the semiconductor wafer 200 is then transferred to the washing/drying unit 113 in step S7, and then subjected to washing and drying process therein in step S8. The semiconductor wafer 200 is taken out from the CMP system after the drying process in step S9.

The semiconductor wafer 200 has an excellent smooth top surface wherein the Cu film 205 is embedded in the trench pattern 203. The semiconductor wafer 200 is then subjected to a large number of processing for forming a circuit structures having damascene pattern thereon.

The CMP process as described heretofore is expected to provide an optimum surface structure by using two different CMP units for the Cu film and the barrier film. However, it is noted by the present inventor after investigating the surface of the semiconductor wafer that the sheet resistance of the damascene interconnect pattern is not uniform.

It was confirmed by the analysis of the wafer surface that the ununiformity of the sheet resistance resulted from excessive polishing called erosion or dishing on the surface of the Cu film 205, such as shown in FIG. 5A.

The reason for occurrence of the erosion or dishing was due to the organic Cu complex 206, such as shown in FIG. 5B, attached onto the surface of the wafer 200 after polishing the Cu film 205 for exposing the barrier film 204 The organic Cu complex 206 caused over-polishing of the Cu film 205 during polishing the barrier film 204.

The reason for generation of the organic Cu complex 206 was due to the organic compounds such as silica contained in a polishing liquid used for polishing the Cu film 205, the organic compounds being reacted with the Cu film 205 to form the organic Cu complex 206.

In our experiments, an increase of the time length for the rinsing step after the polishing of the Cu film 205 did not effectively remove the organic Cu complex 206, and exhibited that the longer rising time length was not practical to the CMP process.

The CMP process described in earlier Patent Application 11-315560 employs a pad member made of urethane and polishing slurry for the polishing of the barrier film 204, and employs a pad member made of fixed abrasive grains and a chemical solution as a polishing liquid for the polishing of the conductive film.

Although the fixed abrasive grains of the pad member allows the polishing slurry to include no abrasive grains, the chemical solution inevitably includes organic compounds, and generates an organic Cu complex 206 and thus erosion or dishing.

As described above, it was confirmed that the conventional CMP system 100 does not effectively prevent the occurrence of the erosion or dishing, thereby involving an ununiform sheet resistance of the damascene interconnect pattern.

### SUMMARY OF THE INVENTION

In view of the above, it is an object of the present invention to provide a CMP process and CMP system, which is capable of alleviating the erosion or dishing in the conductive pattern such as a damascene interconnect pattern.

The present invention provides a chemical-mechanical polishing (CMP) process for polishing a surface of a semiconductor wafer including a, barrier film and a conductive film consecutively formed on an insulator film having a trench pattern thereon, the process including the steps of: polishing the conductive film while using an organic polishing liquid until a portion of the barrier film is exposed from the conductive film; cleaning exposed surfaces of the conductive film and the barrier film while using a treatment liquid; washing the exposed surfaces of the conductive film and the barrier film while using a rinsing liquid; polishing the conductive film and the barrier film while using a polishing liquid until a portion of the insulator film is exposed; and washing exposed; surfaces of the conductive film, the barrier film and the insulator film while using a rinsing liquid.

The present invention also provide a chemical-mechanical polishing (CMP) system for polishing a surface; of a semiconductor wafer including a barrier film and a conductive film consecutively formed on an insulator film having a trench pattern thereon, the system including: a first CMP unit for polishing the conductive film while using a polishing liquid until a portion of the barrier film is exposed from the conductive film; a cleaning unit for cleaning, after polishing by the first CMP unit, exposed surfaces of the conductive film and the barriers film while using a treatment liquid; a first washing unit for washing, after the cleaning by the cleaning unit, the exposed surfaces of the conductive film and the barrier film while using a rinsing liquid; a second CMP unit for polishing, after washing by the first washing units the conductive film and the barrier film while using a polishing liquid until a portion of the insulator film is exposed; and a second washing unit for washing, after polishing by the second CMP unit, exposed surfaces of the conductive film, the barrier film and the insulator film while using a rinsing liquid.

In accordance with the CMP process and CMP system of the present invention, the organic Cu complex formed on and attached onto the surface of the wafer during polishing the conductive film can be removed by the function of the rising liquid before the polishing of the barrier film, whereby the erosion or dishing as encountered in the conventional technique does not occur.

The above and other objects, features and advantages of the present invention will be more apparent from the following description, referring to the accompanying drawings.

### BRIEF DESCRIPTION OF THE DRAWINGS

FIG. 1 is a schematic block diagram of a conventional CMP system.

FIGS. 2A to 2C are sectional views of a semiconductor wafer consecutively showing the fabrication steps of a typical CMP process.

FIG. 3 is a schematic perspective view of a CMP unit of the conventional CMP system of FIG. 1.

FIG. 4 is a flowchart of the conventional CMP process used in the CMP system of FIG. 1.

FIG. 5A is a sectional view of a semiconductor wafer having an ununiform sheet resistance for the conductive layer.

FIG. 5B is a sectional view of the semiconductor wafer having an organic Cu complex on the wafer surface.

FIG. 6 is a flowchart of a CMP process according to an embodiment of the present invention.

FIG. 7 is a CMP system according to an embodiment of the present invention.

FIG. 8 is a graph showing the erosion and dishing in the wafer surface after the process of the present embodiment and the conventional process.

FIGS. 9A and 9B are graphs showing the sheet resistances of the damascene patterns formed by the process of the present embodiment and the conventional process, respectively.

FIGS. 10A and 10B are graphs showing the sheet resistances of the damascene patterns formed by the process of the present embodiment and the conventional process, respectively.

FIG. 11 is a schematic block diagram of a first modification of the CMP system of FIG. 7.

FIG. 12 is a flowchart of a !first modification of the CMP process of FIG. 6.

FIG. 13 is a flowchart of a second modification of the CMP process of FIG. 6.

FIG. 14 is a schematic block diagram of a third modification of the CMP system of FIG. 7.

FIG. 15 is a schematic block diagram of a further modification of the CMP system of FIG. 11.

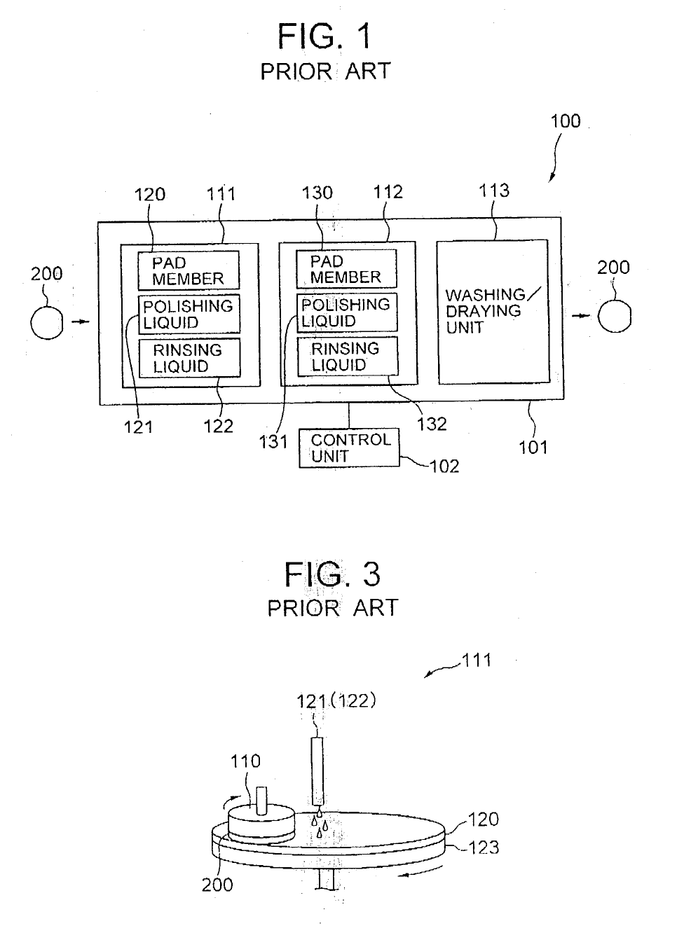

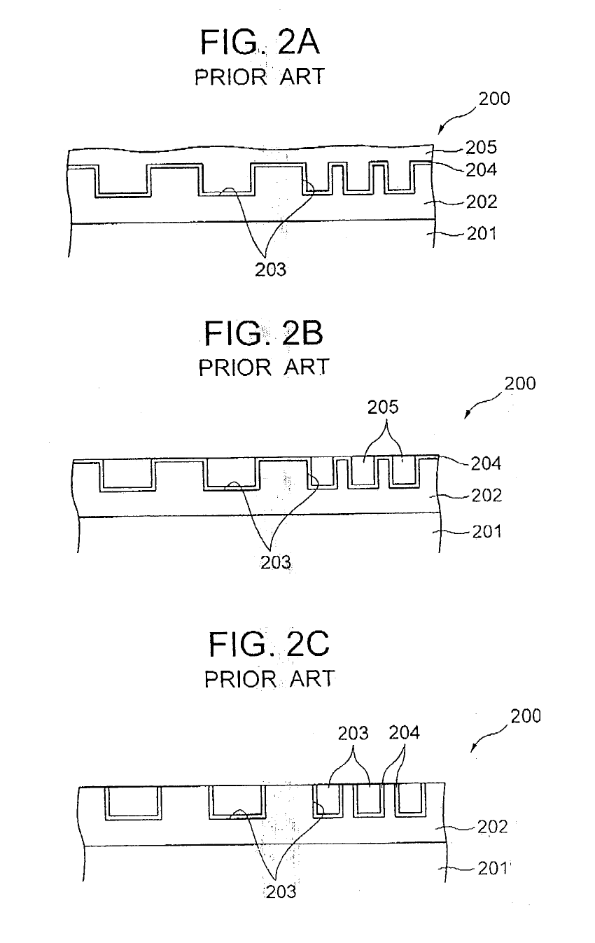

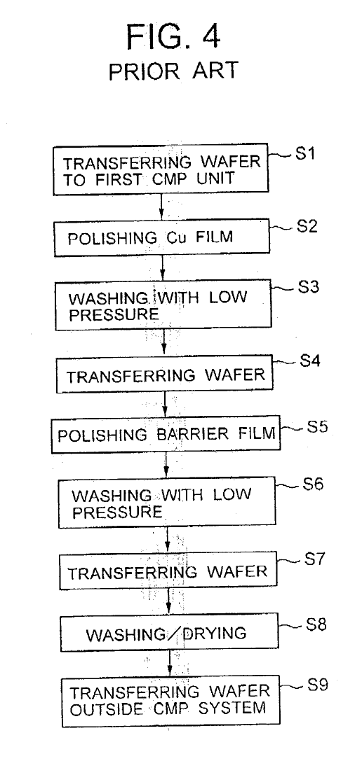

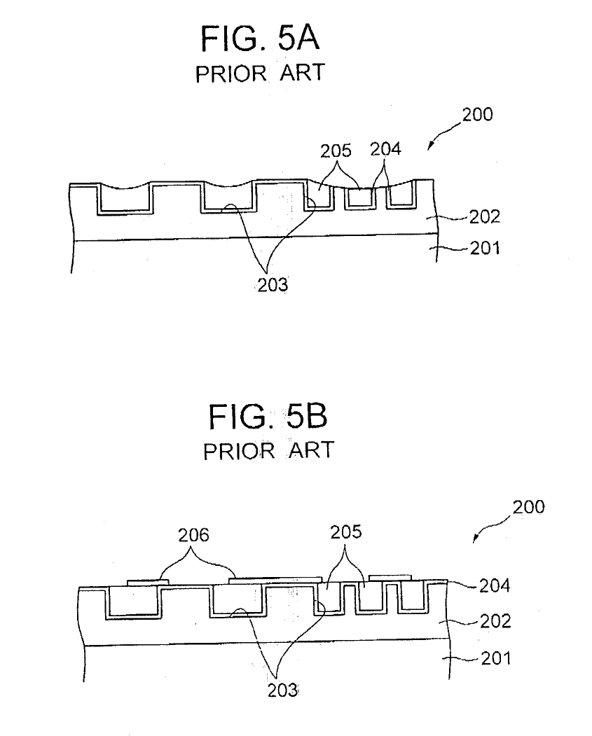

### PREFERRED EMBODIMENTS OF THE INVENTION

Now, the present invention is more specifically described with reference to accompanying drawings, wherein similar constituent elements are designated by similar reference numerals throughout the drawings.

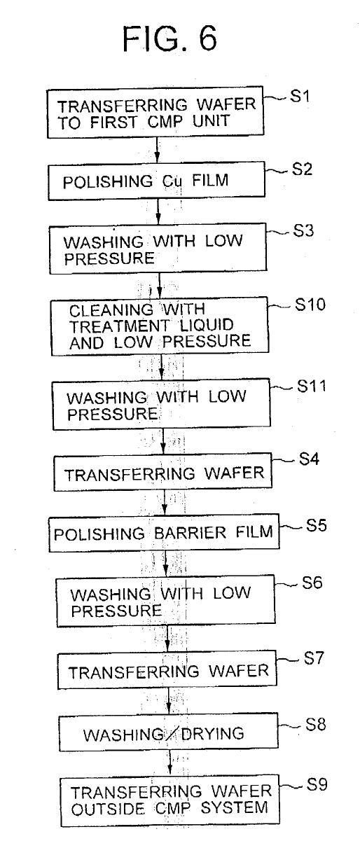

Referring to FIG. 6, a CMP process according to an embodiment of the present invention includes steps S1 to S11, wherein steps S10 and S11 are added to the steps S1 to S9 of the conventional process between the, steps S3 and S4 in FIG. 3.

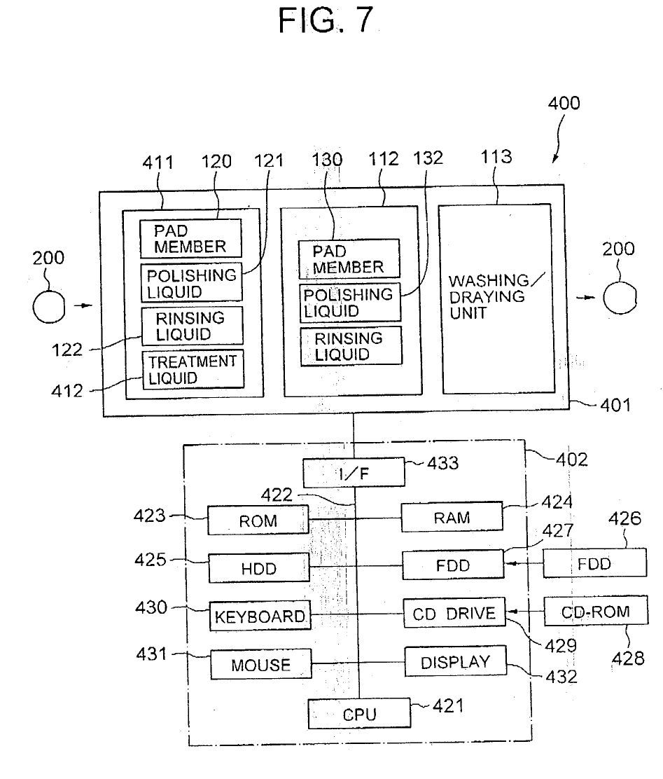

Referring to FIG. 7, the CMP system 400 implementing the CMP process of FIG. 6 includes a CMP plant 401 and a control unit 402.

The CMP plant 401 includes a first CMP unit 411, a second CMP unit 112 and a washing/drying unit 113, consecutively disposed similarly to the conventional CMP system 100. The first CMP unit 411 has an additional member 412 in addition to the pad member 120, the polishing-liquid supply member 121 add the rinsing-liquid supply member 122, which are similar to those in the conventional CMP system. The additional member has a function of supplying a treatment liquid, or aqueous ammonium in this embodiment, onto the surface of the pad member 120. The second; CMP unit 112 and the washing/drying unit 113 are also similar to those in the conventional CMP system.

The control unit 402 is implemented by a computer system, which includes a central processing unit (CPU) 421, bus lines 422, and a ROM 423, a RAM 424, a HDD 425, a FDD 427 on which a FD 426 is mounted, a CD drive 429 on which a CD-ROM 428 is mounted, a key board 430, a mouse 431, display unit 432 and an interface 433, which are coupled to the CPU 421 via the bus lines 422.

A control program for the CPU 421 and the data for processing are stored in at least one of the ROM 423, RAM 424, HDD 425, FD 426 and CD-ROM 428 which constitute storage devices.

For example, the control, programs to be executed by the CPU 421 are stored in the FD 426 or CD-ROM 428. These programs are installed therefrom in the HDD 425 beforehand, copied to the RAM 424 upon start of the system, and then read therefrom by the CPU.

By executing the programs on the CPU 521, the CMP system, in combination with the hardware of the CMP plant, logically implements the first polishing member, first washing member, cleaning member, second washing member, second polishing member, third washing member etc. as functional members.

The first polishing member has a function for rotating the pad member 120, supplied with a polishing liquid by a polishing liquid supply member 121 of the first CMP unit 411, to polish the surface of the semiconductor wafer 200 while thrusting the wafer 200 against the pad member 120 with a high thrust pressure of 4 psi by the thrust member.

The first washing member has a function for rotating the pad member 120, supplied with a rinsing liquid by a rinsing liquid supply member 122 of the first CMP unit 411 after the polishing by the first polishing member, to rotate the semiconductor wafer 200 while thrusting the wafer 200 against the pad member 120 with a low thrust pressure of 1 psi.

The cleaning member has a function for rotating the pad member 120, supplied with a treatment liquid by the treatment liquid supply member 412 of the first CMP unit 411 after the washing by the first washing member, to rotate the semiconductor wafer 200 while thrusting the wafer 200 with a low thrust pressure of 1 psi.

The second washing member has a function for rotating the pad member 120, supplied with a rinsing liquid by a rinsing liquid supply member 122 of the first CMP unit 411 after the cleaning by the cleaning member, to rotate the semiconductor wafer while thrusting the wafer 200 against the pad member 120 with a low thrust pressure of 1 psi.

The second polishing member and the third washing member have functions similar; to those of the first polishing member and the first washing member, respectively, except for the hardware of the CMP plant, which is the second CMP unit 112 for the second polishing member and the third washing member. Those functional members are implemented mainly by the software stored in the RAM 424 etc. for the CPU 421.

The software is stored in the RAM 424 etc. for executing the consecutive steps of rotating the pad member 120 supplied with a polishing liquid to rotate the semiconductor wafer 200 while thrusting the wafer 200 with a high thrust pressure by the pad member 120, rotating the pad member 120 supplied with a rinsing liquid to rotate the semiconductor wafer 200 while thrusting the wafer with a low pressure by the pad member 120, rotating the pad member 120 supplied with the treatment liquid to rotate the semiconductor wafer 200 while thrusting the wafer, 200 with a low thrust pressure by the pad member, rotating the pad member 120 supplied with a rinsing liquid to rotate the semiconductor wafer 200 while thrusting the wafer 200 with a low thrust pressure by the pad member 120 and so on.

Back to FIG. 6, in operation of the CMP system of FIG. 7, a semiconductor wafer 200 is transferred to the CMP system 400, and placed on the first CMP unit 411 in step S1.

A polishing liquid is supplied from the polishing liquid supply member 120 in the first CMP unit 411 to the top of the pad member 120, which is driven, for a horizontal rotation. The semiconductor wafer 200 is thus rotated while being thrust against the pad member 120 with a thrust pressure of 4 psi, and the exposed conductive film (Cu film) of the wafer 200 is polished until the barrier film is exposed therefrom, in step S2.

The thrust pressure for the semiconductor wafer 200 is then reduced from 4 psi to 1 psi, and a rinsing liquid is supplied from the rinsing liquid supply member 122 to the top of the pad member 120, whereby the semiconductor wafer 200 is washed in step S3 after the polishing thereof.

The semiconductor wafer 200 is then subjected to cleaning and washing in the first CMP unit 411 in steps S10 and S11.

More specifically, a treatment liquid is supplied onto the top of the pad member 120 from the treatment liquid supply member 412, with the thrust pressure for the semiconductor wafer 200 by the thrust member being maintained at the low pressure whereby the organic Cu complex attached onto the exposed surface of the semiconductor wafer 200 is removed in step S10 by the treatment liquid.

Subsequently, a rinsing liquid is supplied onto the top of the pad member 120 from the rinsing liquid supply member 122, with the thrust pressure by the pad member 120 is maintained the low pressure, whereby the removed organic Cu complex on the surface of the semiconductor wafer 200 is washed way together with the treatment liquid in step, S11.

The steps S4 to S7 subsequent to step S11 in the present embodiment is similar to those in the conventional technique, and thus the detail of the steps S4 to S7 is not iterated herein for avoiding a duplication.

The CMP process used in the CMP system 400 features steps 510 and 511, wherein the surface of the semiconductor wafer 200, which is subjected to rinsing in step S3 after polishing the Cu film, is cleaned and washed by using the treatment liquid and the rinsing liquid, respectively, prior to the polishing of the barrier film 204.

The cleaning in step S10 preferably uses aqueous ammonium as the treatment liquid, and the washing in steps S3, S6, and S11 preferably uses pure water as the rinsing liquid. Preferable aqueous ammonium includes ammonium at 1% or less, 0.5%1 for example, by weight of the total aqueous ammonium. By using the aqueous ammonium as the treatment liquid, the cleaning step S10 cleans the exposed surface of the semiconductor wafer and effectively removes or peels the organic Cu complex attached onto the exposed surface By using the pure water as the rinsing liquid, the rinsing step S11 washes away the aqueous ammonium and the removed organic Cu complex from the surface of the semiconductor wafer.

The removal of the organic Cu complex 206 prevent occurrence of the erosion or dishing, on the surface of the Cu film 205 during polishing the barrier film 204, whereby a superior damascene interconnect pattern having a uniform sheet resistance can be obtained on the semiconductor wafer 200.

The present invention is preferably applied to the semiconductor wafer having a Cu film as the conductive film and an underlying barrier film. The polishing liquid for the Cu film generally includes an organic compound, which is readily reacted with Cu to form an organic Cu complex 206 on the wafer surface. The organic Cu complex can be effectively removed from the surface of the wafer by the aqueous ammonium and washed away from the surface by the pure water together with the aqueous ammonium.

The polishing of the Cu film and rinsing, cleaning and rinsing of the exposed surface of the resultant wafer are all executed in the first CMP unit 411, which raises the throughput of the CMP processing by obviating the transfer of the wafer.

The first rinsing, the cleaning and the second rinsing steps are consecutively executed by rotating the pad member 120 while thrusting the semiconductor wafer with a low pressure. This simplifies processings for the CMP process.

The CMP system 400 of the present embodiment uses the treatment liquid supply member 412 additionally to the conventional CMP system, need not use a dedicated pad member or brush member, and thus does not complicate or enlarge the structure of the CMP system 400.

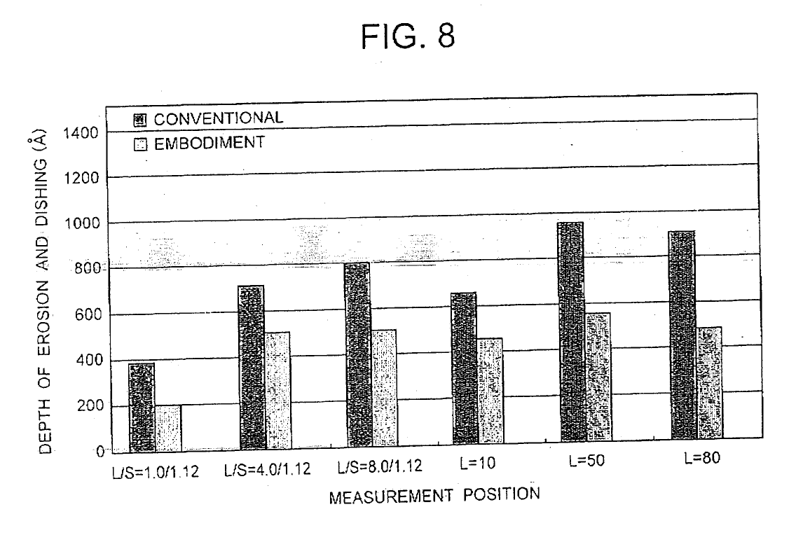

Samples of the semiconductor wafer were subjected to CMP process using the CMP system 400 of the present embodiment and the conventional CMP system 100, and to measurements for the depth of erosion or dishing. The results of the measurements are shown in FIG. 8, wherein the depth of erosion or dishing is plotted on ordinate against the measurement position of the surface of the wafer plotted on abscissa. FIG. 8 reveals that the CMP system 400 of the present embodiment is superior to the conventional CMP system 100 because the measured depths are reduced down to about 60 to 70% by the CMP system 400 of the present embodiment compared to the conventional CMP system 110.

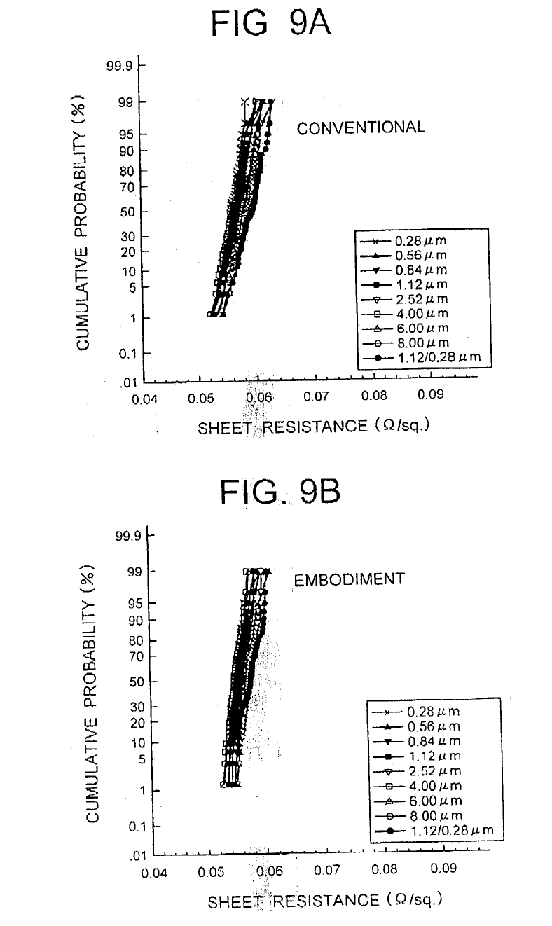

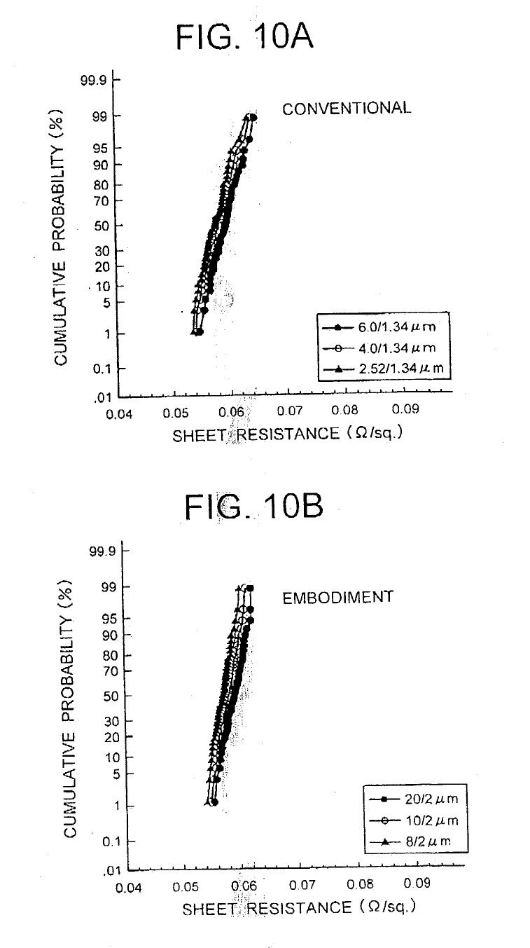

Other samples of the semiconductor wafer were also subjected to similar CMP processing and measurements for sheet resistance of the damascene interconnect pattern. The results of the measurements for the conventional CMP process and the CMP process of the embodiment are shown in FIGS. 9A and 9B, respectively, for different widths of the interconnect patterns having a thickness of 0.28 μm. As will be understood from these drawings, the sheet resistance and variance thereof for the embodiment are lower than those for the conventional process. FIGS. 10A and 10B are similar; graphs for showing the results of semiconductor wafers including interconnect patterns having different widths and different thicknesses. The present invention is not limited to the configuration of the first embodiment and may have different configurations, such as follow.

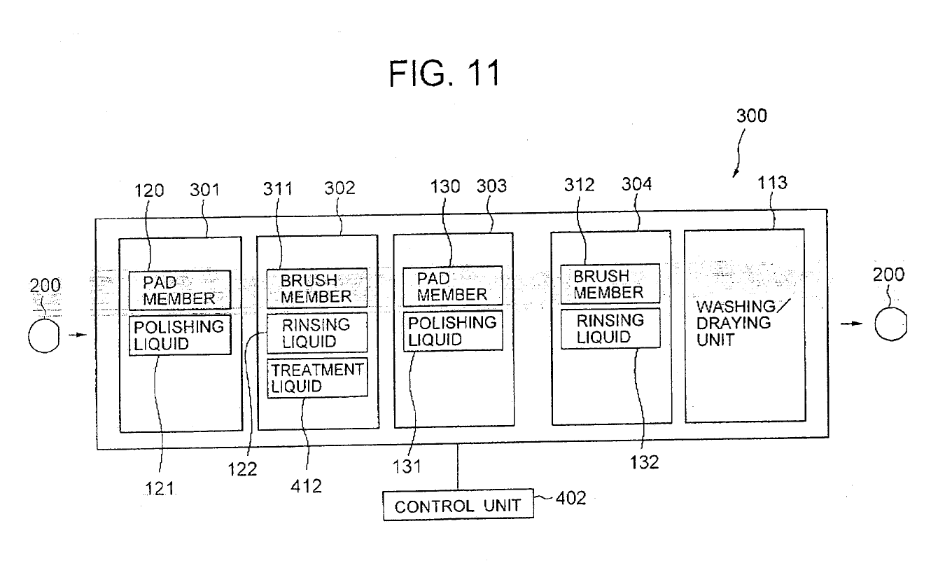

Referring to FIG. 11, a CMP system 300 according to a first modification of the embodiment of FIG. 7 includes a first CMP unit 301, a first washing unit 302, a second CMP unit 303, a second washing unit 304 and i a washing/drying unit 113 consecutively arranged in this order. The first and second CMP units 301 and 303 polish the semiconductor wafer 200 by using pad members 120 and 130 in association with the polishing liquid supply members 121 and 131 whereas the first and second washing units 302 and 304 wash the semiconductor wafer 200 by using brush members 311 and 312 in association with rinsing liquid supply member 122 and 132. The first washing unit 302 includes a treatment liquid supply member 412 therein.

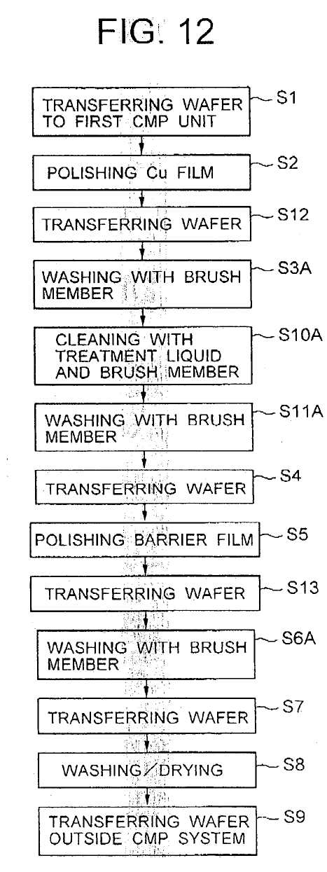

Referring to FIG. 12, a CMP process used in the CMP system 300 of the first modification includes a washing step S3A, a cleaning step S10A and a washing step S11A consecutively executed in the first washing unit 302 using a brush member prior to polishing the barrier film. This does not increase the scale of the CMP system 300.

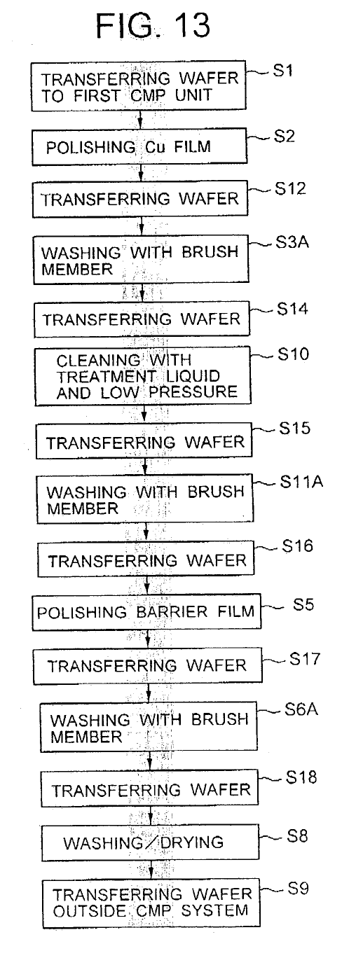

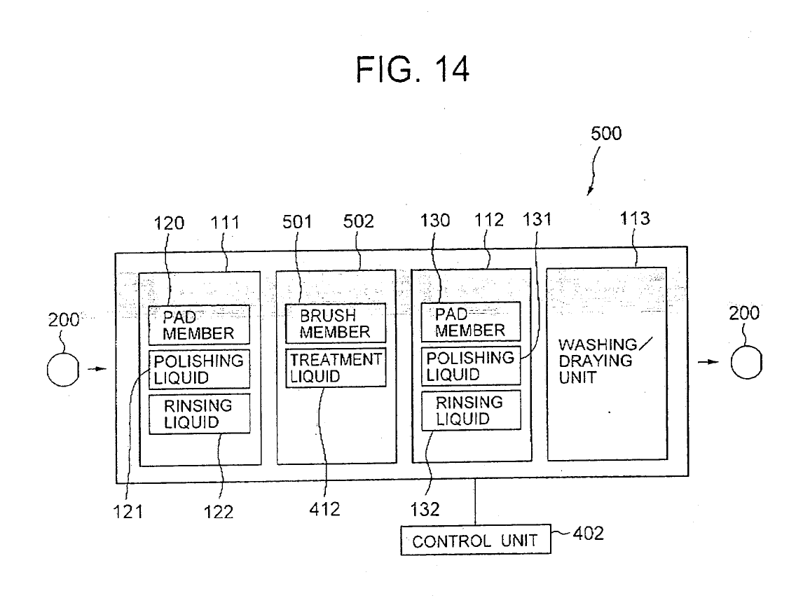

In a second modification, the treatment liquid supply unit 412 may be disposed in the first CMP unit 301 instead of the first washing unit 302. In the second modification, as shown in: FIG. 13, the: semiconductor wafer, after subjected to washing by the first washing unit 302 in step S3A is returned to the first CMP unit 301 in step S14, wherein the surface of the semiconductor wafer is cleaned with the pad member while supplying the treatment liquid in step S10. After the cleaning in step S10, the semiconductor wafer is again transferred in step. S15 to the first washing unit 302, wherein the surface of the semiconductor wafer is again washed in step S11A to wash way the removed organic Cu complex and the treatment liquid.

In a third modification of the embodiment, the CMP system 500 includes a dedicated cleaning unit 502, which uses a brush member 501 and a treatment liquid supply unit 412, between the first CMP unit 111 and the second CMP unit 112. In the third modification, the semiconductor wafer 200, after being subjected to polishing and washing steps in the first CMP unit 111, is transferred to the cleaning unit 502 for cleaning and washing therein by using a treatment liquid and a rinsing liquid, respectively.

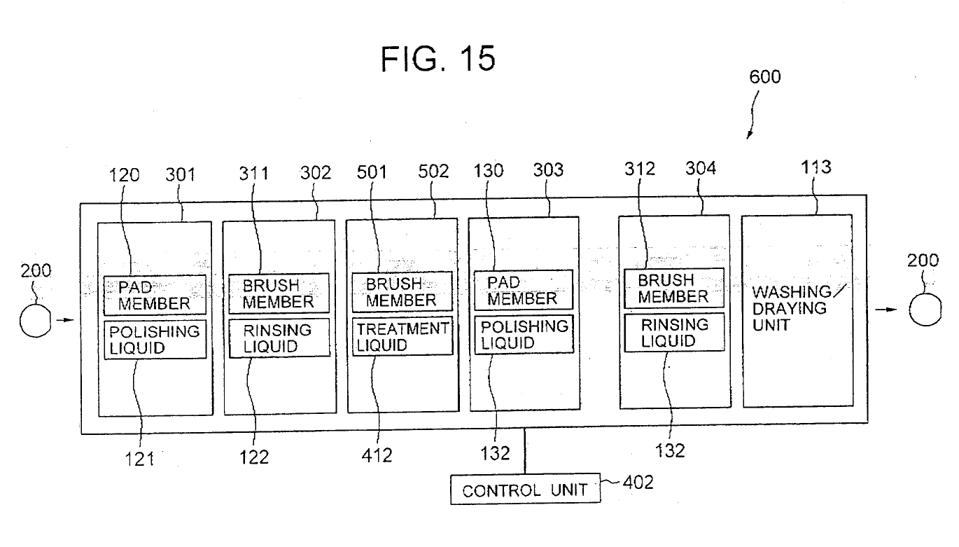

Referring to FIG. 15, in a further modification from the first modification of FIG. 11, a CMP system 600 includes a dedicated cleaning unit 501 between the first washing unit 302 and the second CMP unit 303 shown in FIG. 11 instead of using the treatment liquid supply member 412 in the first washing unit 302. In this modification, the semiconductor wafer 200, after being subjected to washing in the first washing unit 302, is transferred to the cleaning unit 502, wherein the semiconductor wafer. 200 is subjected to cleaning using a treatment liquid for a removing organic Cu complex The semiconductor wafer 200 is then returned to the first washing unit 302 for washing way the removed organic Cu complex.

In the above modification of FIG. 15, the first washing/step after polishing the Cu film and prior to the cleaning step for the organic Cu complex may be omitted. In this case, the order of the arrangement for the first washing unit 302 and the cleaning unit 502 may be preferably reversed.

In the above embodiments and the modifications, E the polishing steps for the Cu film or conductive film and the barrier film exemplarily use pad members 120 and 130 made of urethane in combination with the polishing liquid or slurry. However, The polishing step for the Cu film may use a pad member made of fixed abrasive grains in combination with a chemical solution.

The rinsing liquid is preferably pure water. The treatment liquid may be an alkali solution for a carboxyl acid solution. The alkali solution may be preferably aqueous ammonium or an electrolyte including ammonium, wherein alkali solution preferably includes ammonium at 1% or less. The polishing liquid generally includes an organic compound.

In addition some of the functions of the program for the CPU may be implemented by dedicated hardware instead.

Since the above embodiments are described only for examples, the present invention is not limited to the above embodiments and various modifications or alterations can be easily made therefrom by those skilled in the art without departing from the scope of the present invention.

What is claimed is:

1. A chemical-mechanical polishing (CMP) process for polishing a surface of a semiconductor wafer including a barrier film and a conductive film consecutively formed on an insulator film having a trench pattern thereon, said process comprising the steps of:
polishing said conductive film while using an organic polishing liquid until a portion of said barrier film is exposed from said conductive film;
cleaning exposed surfaces of said conductive film and said barrier film while using a treatment liquid;
washing said exposed surfaces of said conductive film, and said barrier film while using a rinsing liquid;
polishing said conductive film and said barrier film, while using a polishing liquid until a portion of said insulator film, is exposed; and
washing exposed surfaces of said conductive film, said barrier film and said insulator film while using a rinsing liquid.

2. The CMP process as defined in claim 1, wherein said treatment liquid is either an alkali solution or a carboxylic acid solution.

3. The CMP process as defined in claim 2, wherein said alkali solution is aqueous ammonium or an electrolyte including ammonium.

4. The CMP process as defined in claim 3, wherein said rinsing liquid is pure water.

5. The CMP process as defined in claim 3, wherein said aqueous ammonium includes ammonium at 1% or less by weight.

6. The CMP process as defined in claim 1, wherein said polishing, washing and cleaning use a single pad member rotating on said semiconductor wafer.

7. The CMP process as defined in claim 6, wherein said semiconductor wafer is thrust against said pad member with a first thrust pressure during said polishing, and thrust during said washing and cleaning with a second thrust pressure lower which is than said first thrust pressure.

8. The CMP process as defined in claim 1, wherein said polishing uses a pad member, and said washing and said cleaning use a brush member.

9. The CMP process as defined in claim 1, wherein said polishing and said washing use a pad member, and said cleaning uses a brush member.

10. The CMP process as defined in claim 1, further comprising, between said polishing of said conductive film and said cleaning step, the step of washing said exposed surfaces of said conductive film and said barrier film while using a rinsing liquid.

11. The CMP process as defined in claim 1, wherein said conductive film is a Cu film.

12. The CMP process as defined in claim 11, wherein said cleaning step removes an organic Cu complex.

13. The CMP process as defined in claim 12, wherein said treatment liquid is either an alkali solution or a carboxylic acid solution.

14. The CMP process as defined in claim 13, wherein said alkali solution is aqueous ammonium or an electrolyte including ammonium.

15. The CMP process as defined in claim 13, wherein said rinsing liquid is pure water.

16. The CMP process as defined in claim 13, wherein said aqueous ammonium includes ammonium at 1% or less by weight.

17. A chemical-mechanical, polishing (CMP) system for polishing a surface of a semiconductor wafer including a barrier film and a conductive film consecutively formed on an insulator film having a trench pattern thereon, said system comprising:
a first CMP unit for polishing said conductive film while using-a polishing liquid until a portion of said barrier film is exposed from said conductive film;
a cleaning unit for cleaning, after polishing by said first CMP unit, exposed surfaces of said conductive film and said barrier film while using a treatment liquid;
a first washing unit for washing, after said cleaning by said cleaning unit, said exposed surfaces of said conductive film and said barrier film while using a rinsing liquid;
a second CMP unit for polishing, after washing by said first washing unit said conductive film and said barrier film while using a polishing liquid until a portion of said insulator, film is exposed; and
a second washing unit for washing, after polishing by said second CMP unit, exposed surfaces of said conductive films said barrier-film and said insulator film while using a rinsing liquid.

18. The CMP system as defined in claim 17, further comprising a third washing unit for washing, after said polishing by said first CMP unit, said exposed surfaces of said conductive film and said barrier film while using a rinsing liquid.
